(19) United States
(12) Patent Application Publication
(10) Pub. No.: US 2026/0251497 A1
(43) Pub. Date: Aug. 27, 2026

(54) SYNCHRONIZED TESTING OF LIGHT EMITTING DIODES

(71) Applicant: Advantest Corporation, Tokyo (JP)

(72) Inventor: Karl George PEDERSEN, JR., San Jose, CA (US)

(21) Appl. No.: 19/065,765

(22) Filed: Feb. 27, 2025

(51) Int. Cl. G01J 1/42; G01J 1/04; G01J 3/02; G01J 3/28

(52) U.S. Cl. CPC G01J 1/42; G01J 1/0425; G01J 3/0218; G01J 3/28; G01J 2001/4252

(57) ABSTRACT

Test systems and methods are described. In one example, probe pairs are connected to a subset of a plurality of light emitting diodes (LEDs) of a wafer. Energizing pulses are sequentially applied through the probe pairs. The energizing pulses each energize individual LEDs or LED groups. Contiguous ones of the energizing pulses are activated with at least partial concurrence. Luminance measurements are detected using a photodetector assembly that is statically positioned to detect light emitted by all of the subset of the plurality of LEDs connected to the probe pairs.

### BACKGROUND

### Field of the Various Embodiments

This application relates to systems and methods for reliable quality control tests for light emitting diode (LED) devices and components, and more specifically, to techniques for synchronized testing of LEDs, for example, prior to singulation.

### Description of the Related Art

Reliable quality control testing for LEDs often involves measuring light output and/or efficiency. An LED light output test measures the light output that an LED produces. The test generally identifies whether the LED emits at an expected brightness and with an expected spectrum. However, one drawback of existing light output measurement methods is that they are often limited to measuring a single LED at a time. For example, one common method for measuring LED light output involves surrounding an individual LED with an integrating sphere and measuring the total light that the LED outputs into the integrating sphere. However, the integrating sphere is limited to testing a single device at a time.

Another drawback of existing light output measurement techniques is that many LEDs, including micro-LEDs (also referred to as MicroLEDs, mLEDs and/or μLEDs) are manufactured on a wafer and must be probe tested prior to singulation. Mounting an integrating sphere around the LED during a probe test is physically impractical. In addition, integrated sphere techniques and other existing techniques such as spatially discriminating photodetectors are impractically slow for LED device arrays with many LEDs because of the constant need to move the integrating sphere for each LED being tested.

As the foregoing illustrates, what is needed in the art is systems and methods for quality control tests for LEDs, which increase the speed of testing for LED device arrays on a wafer.

### SUMMARY

One embodiment of the present disclosure sets forth a system that includes a chuck that holds a wafer that includes LEDs, a probe device that includes probe pairs that connect to a probed subset of the LEDs, a photodetector assembly that is statically positioned to detect light emitted by all of the probed LED subset, and at least one computing device that energizes the probed LED subset by sequentially applying a plurality of energizing pulses that are synchronized with luminance and/or spectral measurement timing for LED testing. Individual probe pairs connect to individual LEDs. Individual ones of the energizing pulses energize individual ones of the probed LEDs. Contiguous energizing pulses of the pattern are activated with at least partial concurrence (e.g., overlapping in time).

Further embodiments set forth a computer-implemented method and non-transitory computer-readable media that stores instructions that perform the method when executed, where the method includes connecting probe pairs to a subset of a plurality of light emitting diodes (LEDs) of a wafer; sequentially applying a plurality of energizing pulses through the plurality of probe pairs, where the plurality of energizing pulses each energize individual ones of the subset of the plurality of LEDs, and where contiguous ones of the plurality of energizing pulses are activated with at least partial concurrence; and synchronously detecting one or more luminance measurements for the subset of the plurality of LEDs using a photodetector assembly that is statically positioned to detect light emitted by all of the subset of the plurality of LEDs.

At least one technical advantage of the disclosed techniques relative to the prior art is that the disclosed techniques enable fast and reliable luminance testing of LEDs prior to singulation. Another technical advantage is that the speed and efficiency of luminance testing is increased relative to existing techniques for luminance testing on wafer and/or prior to singulation. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, can be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates an example LED testing system, according to various embodiments.

FIG. 2 illustrates an example of a wafer and a subset of LEDs probed by the LED testing system of FIG. 1, according to various embodiments.

FIG. 3 illustrates an example of multiple LED subsets in a single wafer sector of a wafer probed by the LED testing system of FIG. 1, according to various embodiments.

FIG. 4 illustrates an example of a probed LED subset and a current and luminance graph for individual LED testing using the LED testing system of FIG. 1, according to various embodiments.

FIG. 5 illustrates an example of a probed LED subset and a current and luminance graph for LED group testing using the LED testing system of FIG. 1, according to various embodiments.

FIG. 6 illustrates an example of LED probe pairs and probed LEDs of the LED testing system of FIG. 1, according to various embodiments.

FIG. 7 is a flow diagram of method steps for individual LED testing using the LED testing system of FIG. 1, according to various embodiments.

FIG. 8 is a flow diagram of method steps for LED group testing using the LED testing system of FIG. 1, according to various embodiments.

### DETAILED DESCRIPTION

In the following description, numerous specific details are set forth to provide a more thorough understanding of the various embodiments. However, it will be apparent to one of skilled in the art that the inventive concepts can be practiced without one or more of these specific details.

The described testing systems include a LED testing system that perform a test of LEDs on a wafer, for example, prior to singulation, and/or removal from the wafer. Singulation refers to cutting or dividing a substrate such as a wafer into separate pieces. In various examples, singulation involves scribing, sawing, laser cutting and/or performing other actions to separate a set of devices of the substrate into individual devices. In this context, the individual devices include LED devices that include one or more LEDs. Reliable quality control testing for LEDs often involves measuring light output and/or efficiency. However, existing light output measurement methods are limited to measuring a single LED at a time. For example, using an integrating sphere that is limited to testing a single LED device. Furthermore, many modern LEDs, including micro-LEDs, are manufactured on a wafer. As a result, it is preferable to perform tests prior to singulation. However, existing light output measurement techniques are not appropriate for on-wafer testing. For example, measurement techniques such as integrated sphere techniques are physically impractical or impossible for on-wafer testing. Techniques that utilize integrated spheres, spatially discriminating photodetectors and the like are impractically slow for LED device arrays with many LEDs, such as micro-LED arrays. For example, existing techniques may probe a single LED at a time, and/or separately energize LEDs.

Some embodiments of the present disclosure set forth a system that includes a chuck that holds a wafer that includes LEDs, a probe device that includes probe pairs that connect to a probed subset of the LEDs, a photodetector assembly that is statically positioned to detect light emitted by all of the probed LED subset, and at least one computing device that energizes the probed LED subset by applying a plurality of sequential energizing pulses. Individual probe pairs connect to individual LEDs. Individual ones of the energizing pulses energize individual ones of the probed LEDs. Contiguous energizing pulses of the pattern are activated with at least partial concurrence (e.g., overlapping in time). Accordingly, the described LED testing techniques enable fast and reliable on-wafer luminance testing prior to singulation, while also increasing speed and efficiency of luminance testing relative to existing techniques.

In some embodiments, the wafer rests on a clear glass or other transparent wafer chuck, rather than a solid metal chuck commonly used in wafer probe systems. The glass chuck in combination with the clear LED substrate allows LED light emissions to propagate through the chuck. A single high-speed photodetector is mounted below the wafer chuck. A light guide conveys light from the entire area (e.g., XY, XZ, or other 2D area) of the probe set to the photodetector. In this way some portion of every LED's light output is guided to the photodetector. The photodetector output is measured by an analog to digital converter, for example, contained in the photodetector device or a connected computing device. In some examples, a precise moment of sampling and conversion is initiated by a trigger signal from a computing device. The drive circuit for each LED site is a programmable VI (e.g., voltage-current) source that biases the LED to a specific value at a precise moment in time. Each test site is independently controlled such that the output to any selection of devices, from none to all, can be effected. A control function in the computing device determines which one (or more) LED output will be energized, and the exact moment to trigger photodetector measurement. As a result the energizing pulses are synchronized with measurements and/or time windows associated with particular LEDs. The synchronizing enables the emission of a single LED to be associated with the photodetector measurement of that particular LED. The energizing electrical current drive of sequentially contiguous LEDs can overlap. However, the sequential timing causes a particular LED to dominate light emission, emitting stable light at the time of luminance measurement. This overlap minimizes the total test time.

In operation, embodiments of the present disclosure step the prober and apply probe connections to multiple LEDs concurrently. The system then sequentially (and in some cases with at least partial overlap), energizes each LED (or group of LEDs) in a configured sequence or pattern. The system synchronously measures light output using a single high-speed photodetector that views the entire probe area. The system records the measured luminance, compares the measured luminance to limits, and records a result (e.g., pass/fail) for the individual LED. This is repeated in quick succession for many LEDs. The prober is then stepped to a next location on the wafer. A more detailed description is provided through a discussion of the following figures.

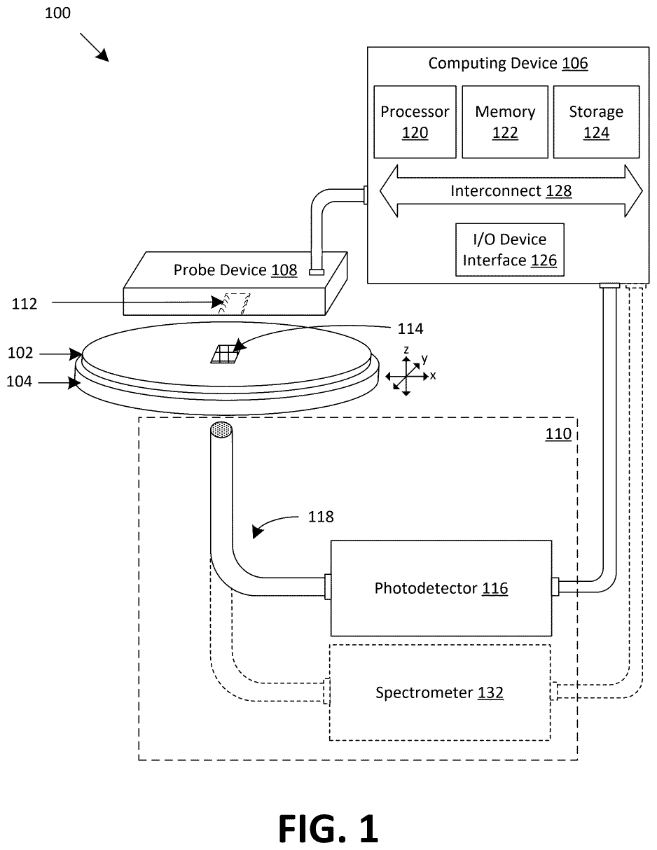

FIG. 1 is an exploded view of an example LED testing system 100, according to various embodiments. The LED testing system 100 tests and/or includes a wafer 102. The LED testing system 100 includes, without limitation, a wafer chuck 104, a computing device 106, a probe device 108, and a photodetector assembly 110. The probe device 108 includes, without limitation, two or more probe pairs 112. The wafer 102 includes, without limitation, one or more wafer sectors 114 that include LEDs. The computing device 106 includes, without limitation, a processor 120, a system memory 122, a storage 124, an input-output (I/O) device interface 126, and an interconnect 128. The photodetector assembly 110 includes, without limitation, a photodetector 116, a light guide 118, and a spectrometer 132.

The wafer 102 refers to a slice of a semiconductor substrate that includes one or more wafer sectors 114 or regions that include LEDs to be tested by the LED testing system 100. Semiconductor substrates used for LEDs include aluminum oxide (Al₂O₃, also known as Sapphire), gallium nitride (GaN), gallium arsenide (GaAs), silicon (Si), aluminum nitride (AlN), and/or the like. In some embodiments, transparent semiconductor substrates are used for devices under test using the LED testing system 100. Transparent semiconductor substrates include aluminum oxide, gallium nitride, gallium arsenide, and others. Transparent semiconductor substrates are transparent (e.g., within a threshold) to at least a portion of the visible light spectrum.

The wafer 102 and the LEDs thereon are formed by various processes such as epitaxy, masking, doping, photolithography, and/or the like. The LEDs on the wafer 102 include micro-LEDs and other types of LEDs. Micro-LEDs refer to microscopic self-emitting or self-illuminated LEDs that form individual pixel elements. Micro-LEDs are LEDs that have a size measured in microns, and are generally less than 100 micrometers in size, which is smaller than (e.g., 1/100^{th} the size of) a conventional LED. In some examples, an array of micro-LEDs is used to form a pixel. However, in various embodiments, a particular wafer sector 114 includes a single color or type of LED rather than an array of LEDs that form a complete pixel in a display or other end-use device. The LEDs in the wafer sector 114 are tested, singulated or otherwise subdivided and removed from the wafer 102 for use and/or further processing. In some examples, subdivision of the LEDs includes separating a set of multiple LEDs from the wafer 102 or separating individual LEDs from the wafer 102 (e.g., singulation). The LEDs of the wafer 102 illuminate toward the wafer chuck 104 and/or in multiple directions including toward the wafer chuck 104. Each LED includes two (or more) contacts that are exposed on a surface of the wafer 102 that faces and/or is closer to the probe device 108 than to the wafer chuck 104 and photodetector assembly 110.

The wafer chuck 104 of the LED testing system 100 holds the wafer 102 in place for testing. In various embodiments, the wafer chuck 104 is formed of a transparent material such as a transparent semiconductor material or substrate. In some embodiments, the wafer chuck 104 is formed using a same material as the wafer 102. In other embodiments, the wafer chuck 104 is formed using a different material than the wafer 102. The wafer chuck 104 holds wafer 102 in place, for example, by creating a vacuum between a surface of the wafer 102 adjacent to a surface of the wafer chuck 104. To this end, some embodiments of the wafer chuck 104 include a pattern of holes and/or grooves from which air to be drawn out using a pump or other device. The pump can be a subcomponent of the wafer chuck 104 and/or the LED testing system 100. In some embodiments, the wafer chuck 104 moves in multiple directions and is operable to connect the probe device 108 to the LEDs of the wafer 102 for testing. For example, the wafer chuck 104 moves laterally (in an x and/or y direction shown and/or rotates in the x-y plane) to align a set of LEDs in the wafer sector 114 with a corresponding and matching set of probe pairs 112 of the probe device 108. In some embodiments, the wafer chuck 104 moves in a y direction to connect the set of probe pairs 112 to the set of LEDs. Once a test of the set of LEDs is completed, the wafer chuck 104 moves in a z direction to disconnect the set of probe pairs 112 from the set of LEDs, and moves laterally in an x and/or y direction to align the set of probe pairs 112 with a new set of LEDs in the wafer sector 114 and/or to move to a new wafer sector 114. In further embodiments, other components of the LED testing system 100 move, such that the probe device 108 and/or the light guide 118 move vertically, and the wafer chuck 104 moves laterally.

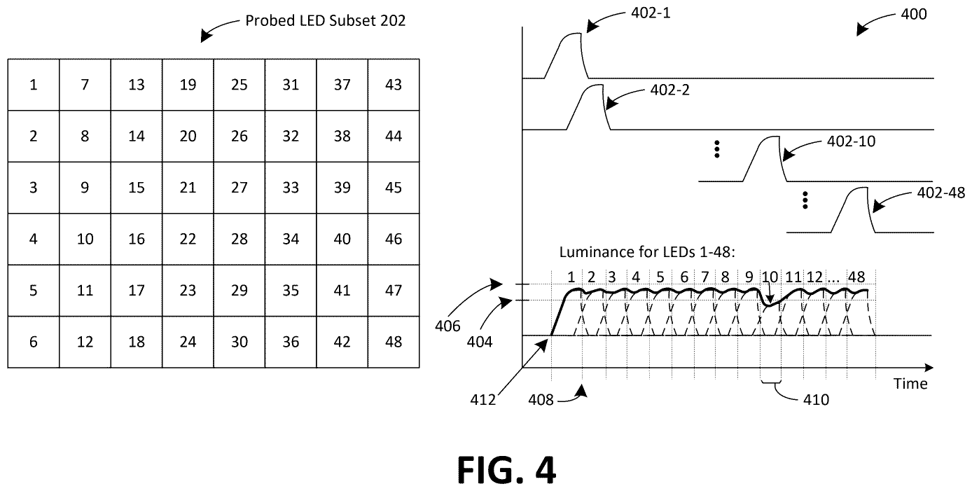

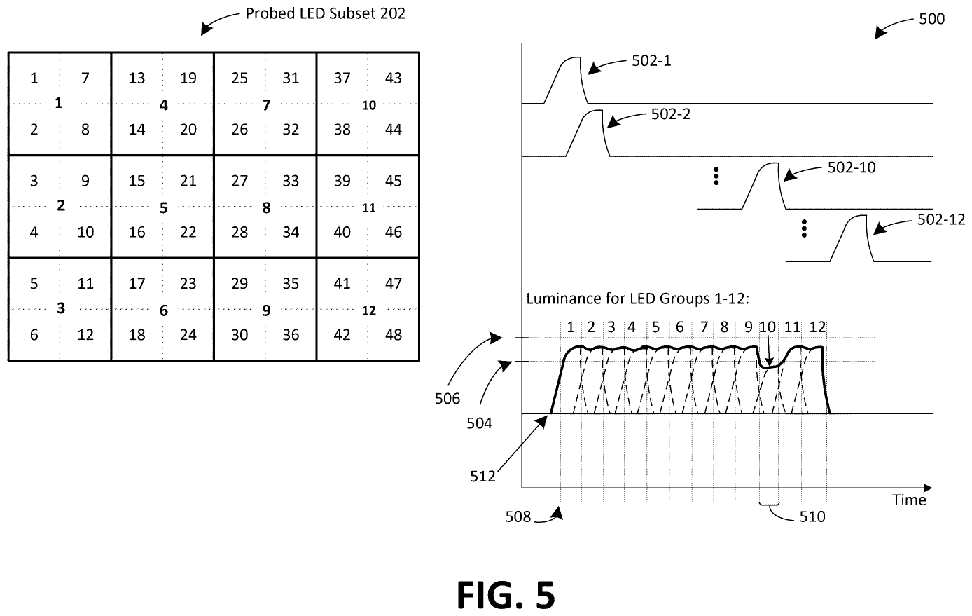

The computing device 106 is configured to implement one or more aspects of the various embodiments. In some examples, the computing device 106 individually controls a set of energizing pulses (e.g., current, voltage, power, etc.) for each LED connected to each probe pair 112 of the probe device 108. Each energizing pulse is provided using a different probe pair 112 of the probe device 108. The computing device 106 sequentially energizes a set of LEDs under test such that contiguous energizing pulses are activated with at least partial concurrence (e.g., overlapping in time), as described in further detail with respect to FIGS. 4 and 5. Alternatively, in some examples, a controller device that is a subcomponent of the probe device 108 controls the energizing pulses for LEDs connected to each probe pair 112 to sequentially energize the set of LEDs. The computing device 106, controller device, and/or other components of the probe device can also work in concert to control the energizing pulses for LEDs connected to each probe pair 112 to sequentially energize the set of LEDs. The computing device 106 is also configured to receive a measurement signal from the photodetector 116, compare the measurement signal to one or more predetermined and/or configurable luminance thresholds (and optionally spectral content thresholds), and record a quality control result (e.g., pass, fail and/or the like) based on the comparison for each individual LED and/or a group of LEDs.

In some embodiments, the computing device 106 includes a processor 120, a memory 122, a storage 124, an I/O device interface 126, and an interconnect 128. Computing device 106 includes a desktop computer, a laptop computer, a smart phone, a personal digital assistant (PDA), tablet computer, or any other type of computing device configured to receive input, process data, and optionally display images, and is suitable for practicing one or more embodiments. Computing device 106 described herein is illustrative and any other technically feasible configurations that fall within the scope of the present disclosure.

Processor(s) 120 includes any suitable processor implemented as a central processing unit (CPU), a graphics processing unit (GPU), an application-specific integrated circuit (ASIC), a field programmable gate array (FPGA), an artificial intelligence (AI) accelerator, any other type of processor, or a combination of different processors, such as a CPU configured to operate in conjunction with a GPU. In general, processor(s) 120 may be any technically feasible hardware unit capable of processing data and/or executing software applications. Further, in the context of this disclosure, the computing elements shown in computing device 106 may correspond to a physical computing system (e.g., a system in a data center) or may be a virtual computing instance executing within a computing cloud.

I/O device interface 126 enables communication of I/O devices with processor(s) 102. I/O device interface 126 generally includes the requisite logic for interpreting addresses corresponding to I/O devices that are generated by processor(s) 102. I/O device interface 126 may also be configured to implement handshaking between processor(s) 102 and I/O devices, and/or generate interrupts associated with I/O devices. I/O device interface 126 may be implemented as any technically feasible CPU, ASIC, FPGA, any other type of processing unit or device. I/O devices include devices capable of providing input, such as a keyboard, a mouse, a touch-sensitive screen, a microphone, a remote control, a camera, and so forth, as well as devices capable of providing output, such as a display device. Additionally, I/O devices may include devices capable of both receiving input and providing output, such as a touchscreen, a universal serial bus (USB) port, and so forth. I/O devices may be configured to receive various types of input from an end-user of computing device 106, and to also provide various types of output to the end-user of computing device 106, such as displayed digital images or digital videos or text. In some embodiments, one or more of I/O devices are configured to couple computing device 106 to a network. A network includes any technically feasible type of communications network that allows data to be exchanged between computing device 106 and external entities or devices, such as a web server or another networked computing device. For example, a network may include a wide area network (WAN), a local area network (LAN), a wireless (WiFi) network, and/or the Internet, among others.

Memory 122 includes a random access memory (RAM) module, a flash memory unit, or any other type of memory unit or combination thereof. Processor(s) 102, I/O device interface 126, and network interface 106 are configured to read data from and write data to memory 122. Memory 122 includes various software programs that can be executed by processor(s) 102 and application data associated with said software programs, including one or more LED testing applications that perform individualized and/or group LED tests.

Storage 124 includes non-volatile storage for applications and data, and may include fixed or removable disk drives, flash memory devices, and CD-ROM, DVD-ROM, Blu-Ray, HD-DVD, or other magnetic, optical, or solid state storage devices. The storage 124 may be a disk drive storage device. Although shown as a single unit, the storage 124 may be a combination of fixed and/or removable storage devices, such as fixed disc drives, floppy disc drives, tape drives, removable memory cards, or optical storage, network attached storage (NAS), or a storage area-network (SAN). Software programs, including one or more LED testing applications that perform individualized and/or group LED tests may be stored in storage 114 and loaded into memory 122 when executed.

The interconnect 128 is inclusive of any technically feasible internal and/or external data busses, memory busses, system busses, expansion busses and/or the like. The interconnect 128 includes a collection of electrical pathways that allows data, addresses, and control signals to be transferred between the various components of the computing device 106 and/or external devices and components. While discussed in the singular for clarity, the interconnect 128 is illustrative of one or more interconnects 128 that connect, for example, the processor 120 to the memory 122 and/or the storage 124, connects the computing device 106 to other devices including the probe device 108, I/O devices, peripheral devices, other computing devices, and/or the like. In some embodiments, the interconnect 128 incudes PCI Express (PCIe) connections for high-speed internal connections and Universal Serial Bus (USB) connections for connecting external devices.

The probe device 108 includes a card or other device that includes multiple probe pairs 112 for connecting to LEDs on the wafer 102. Each probe pair 112 connects to an individual LED in the wafer sector 114. In some examples, a set of probe pairs 112 of the probe device 108 connects to a corresponding set of all LEDs in the wafer sector 114. In other examples, the set of probe pairs 112 connects to a subset of the LEDs in the wafer sector 114. The probe device 108 and/or the computing device 106 stores LED location data that indicates a position of a wafer sector 114, each subset of the LEDs in the wafer sector 114, and/or each individual LED on the wafer. The probe device 108 and/or the computing device 106 uses the LED location data to connect the probe pairs 112 to a set of LEDs on the wafer 102. Once the set of LEDs is tested, the probe device 108 and/or the computing device 106 uses the LED location data to disconnect the probe pairs 112, move one or more components of the LED testing system 100 to another location, and connect the probe pairs 112 to another set of LEDs.

In some embodiments, the light guide 118 includes a fiber optic bundle, such as a group or bundle of individual optical fiber strands. In some embodiments, the group of optical fiber strands are held together, for example, using a jacket, sheath and/or the like. A first end of the light guide 118 is positioned such that at least a portion of the light emitted by each one of the LEDs in the wafer sector 114 and/or each of the LEDs connected to the probe pairs 112 of the probe device 108 enters the first end of light guide 118. A second end of the light guide 118 is positioned such that the light that enters the first end of light guide 118 is guided to the single photodetector 116.

The photodetector 116 or photosensor includes any device or sensor that detects light, such as a photodiode, avalanche photodiode, phototransistor, PIN photodiode, Schottky photodiode, other p-n junction device and/or the like. In some embodiments, light guide 118 includes a first subset of the fiber optic strands that provides light to the photodetector 116, and a second subset of the fiber optic strands that provides light to a spectrometer 132 as indicated by the dashed lines. The light guide 118 splits or branches off to provide detected light to both the photodetector 116 and the spectrometer 132. In embodiments where the light guide 118 branches to the photodetector 116 and the spectrometer 132, the subsets of fiber optic strands are distributed, interleaved, or otherwise incorporated together such that the light guide 118 provides each of the photodetector 116 and the spectrometer 132 with a set of fiber optic strands that receive light from all of the LEDs under test. In some embodiments, the spectrometer 132 is utilized as a spot test for a configured or predetermined subset of the LEDs under test. However, in other examples the spectrometer 132 is utilized for all LEDs under test.

Output signals of the photodetector 116 are measured by an analog to digital converter included in or connected to the photodetector 116 and/or the computing device 106. In some examples, a precise moment of sampling and conversion is initiated by a trigger signal from the computing device 106. In some examples, a drive circuit for each LED site is a programmable VI (e.g., voltage-current) source that biases the corresponding LED to a specific value at a precise moment in time. Each test site is independently controlled such that the output to any selection of devices, from none to all, can be effected. A control function in the computing device 106 and/or the probe device 108 determines which one (or more) LED output will be asserted, and the exact moment to trigger measurement using the photodetector 116. This synchronizing enables the emission of each individual LED to be associated with the photodetector measurement of that same LED. The energizing electrical current drive of sequential LEDs can overlap. However, the sequential timing causes a particular LED to dominate, emitting stable light at the time of luminance measurement. This overlap minimizes the total test time.

The spectrometer 132 analyzes the spectrum of light identifying a specific wavelength of the light, while the photodetector 116 measures the overall light intensity or luminance. In some embodiments, the spectrometer 132 includes a dispersing element that separates wavelengths in the light provided through the light guide 118, as well as a sensor such as a photodetector that measures the intensity of each separated wavelength. As a result, the spectrometer 132 detects the spectral content of the light and provides a signal that indicates the spectral content of the light to the computing device 106.

In one example of the operation of the LED testing system 100, the wafer chuck 104 holds a wafer 102 that includes LEDs such as micro-LEDs. The probe device 108 includes probe pairs 112 that connect to a probed subset of the LEDs of the wafer 102. The photodetector assembly 110, including the photodetector 116 and/or the light guide 118 is statically (e.g., during a test of the probed subset of the LEDs) positioned relative to the wafer 102 and/or the wafer chuck 104, to detect light emitted by each LED of the probed LED subset. The computing device 106 (and/or a controller of the probe device 108) sequentially energizes the probed LED subset by applying synchronized energizing pulses such as controlled current voltage or power waveforms that are synchronized with measurement timing. Individual ones of the energizing pulses energize individual ones of the probed LED subset, and contiguous ones of the energizing pulses are activated such that they overlap in time.

The light guide 118 conveys the entire area (e.g., XY as shown) of the wafer sector 114 corresponding to the probe pairs 112 and the LEDs under test. In this way some portion of every LED's light output is brought to photodetector 116, which can be a single photodetector 116. The photodetector 116 detects light emitted by the LEDs under test, over a duration of the test. Because any two contiguous energizing pulses are activated with at least partial concurrence (e.g., overlapping) but without perfect concurrence, the associated LEDs also emit light with at least partial concurrence. The resulting light output passes through the light guide 118 to the photodetector 116, which detects light intensity and provides one or more light measurement signals such as a continuous curve and/or periodic light intensity values over time. The photodetector 116 provides an indication of the detected light as one or more light (e.g., luminance) measurement signals to the computing device 106.

The computing device 106 compares the one or more light measurement signals to one or more luminance thresholds (e.g., low and high) to identify whether the one or more light measurement signals remain within an acceptable range of values. If the one or more light measurement signals indicate that light detected by photodetector 116 remains within an acceptable range of values throughout the total testing period for the LEDs under test, then all LEDs are acceptable. If all LEDs are acceptable, the computing device 106 records a quality control result such as passing, acceptable, and/or the like.

However, if a light measurement signal is outside of (e.g., is less than or greater than) the one or more luminance thresholds, then the computing device 106 identifies an LED associated with anomalous performance and records a quality control result such as failing, unacceptable, and/or the like. The computing device 106 identifies at least one time that the light measurement signal is outside of the one or more luminance thresholds. The computing device 106 maps the time to a time window for a particular LED according to an LED identifier, probe pair identifier and/or the like. The LED identification time window is a duration of time when the particular LED is a primary light source based on the pattern of energizing pulses applied by the computing device 106 (and/or probe device 108). In some embodiments, the time window is a duration of time when a magnitude of an energizing pulse for the particular LED is greater than individual magnitudes of other energizing pulses. The time window is mapped to an energizing pulse for a particular LED. The computing device 106 records a failing quality control result for this LED. The LED testing system 100 then moves one or more components such as the wafer chuck 104, the probe device 108, and/or the light guide 118 to step to the next wafer sector 114. The operation of the LED testing system 100 is faster than existing embodiments.

In some embodiments, the operation of the LED testing system 100 involves concurrently illuminating LED groups such as 2, 3, 4 or any number of LEDs under test concurrently. Each LED group has a same number of LEDs assigned thereto, so that that resulting combined light intensity is similar (e.g., within one or more thresholds) for each LED group that is operating normally. If one or more LEDs in the LED group are not operating correctly, the overall light combined luminance or intensity will decrease and/or increase. If one or more light measurement signals indicate that combined light detected by photodetector 116 remains within an acceptable range of values throughout the total testing period for the LED groups under test, then all LEDs for all LED groups are acceptable. If all LEDs for all LED groups are acceptable, the computing device 106 records a quality control result such as passing, acceptable, and/or the like. If a group light measurement signal is outside of the one or more group luminance thresholds, then the computing device 106 identifies at least one time that the group light measurement signal is outside of the one or more group luminance thresholds. Generally, the group luminance thresholds are greater than the individual LED luminance thresholds because a greater number of LEDs are illuminated concurrently by a single energizing pulse. The computing device 106 maps the time to a time window for a particular LED group according to an LED group identifier, probe pair identifiers and/or the like. The LED group identification time window is a duration of time when the particular LED group is a primary light source based on the pattern of energizing pulses applied by the computing device 106 (and/or probe device 108). The computing device 106 then performs an individual LED test for the LEDs in the LED group. This individual LED test operates as discussed earlier. Because the overall LED group failed, it is likely that one or more LEDs will be associated with light measurement signals outside of one or more individual luminance thresholds. The computing device 106 identifies a time that the light measurement signals for the individual or individualized test is outside of individual luminance thresholds, and maps the time to one or more LEDs.

In an example that includes spectrometer 132, the light output from one or more of the LEDs under test (e.g., from all LEDs or a subset corresponding to a spot-test) passes through the light guide 118 to the spectrometer 132. The spectrometer 132 identifies the spectral content of the light and provides one or more spectral content measurement signals that indicate one or more wavelengths individually and/or as a range of wavelengths. The spectrometer 132 provides an indication of the spectral content as one or more spectral content measurement signals to the computing device 106.

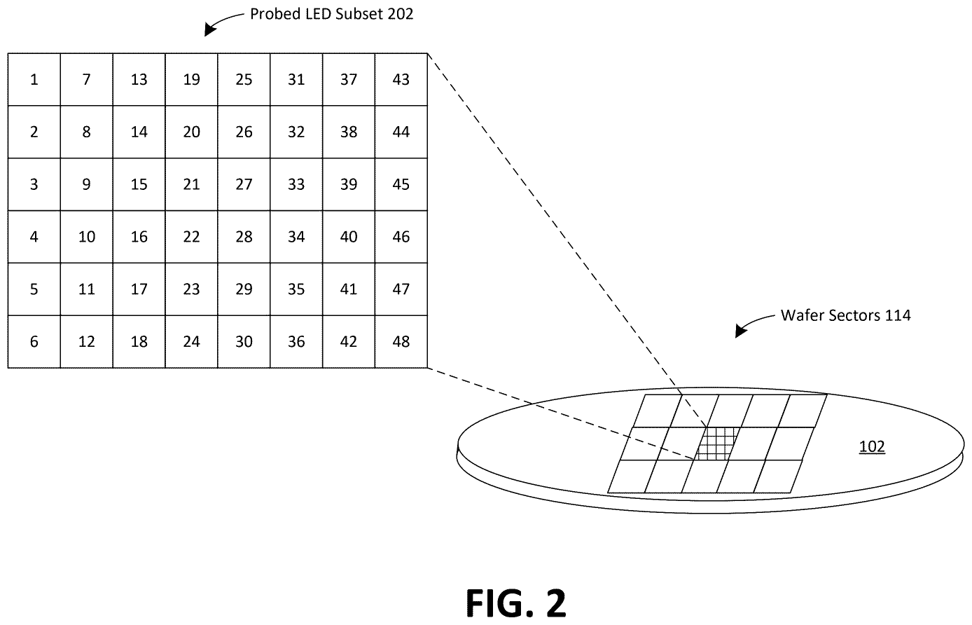

FIG. 2 illustrates an example of a wafer 102 and a probed LED subset 202 probed by the LED testing system 100 of FIG. 1, according to various embodiments. The wafer 102 includes, without limitation, one or more wafer sectors 114. The wafer sector 114 includes, without limitation, a probed LED subset 202 including, without limitation, one or more LEDs shown numbered 1 to 48.

The probed LED subset 202 is a set of LEDs connected to a corresponding set of LED probe pairs 112. Each LED is connected to an LED probe pair 112, so that the LED probe pair 112 provides a current flow through the LED. In the example shown, the probed LED subset 202 is a set of all LEDs in a wafer sector 114. However, in other examples, the probed LED subset 202 is a subset of the LEDs in the wafer sector 114, which are connected to a corresponding set of LED probe pairs 112.

In operation, LED testing system 100 of FIG. 1 connects a probe pair 112 to each LED 1 to 48, such that 48 probe pairs 112 are connected to the 48 LEDs concurrently. For illustrative purposes, the example of FIG. 2 shows a set of 48 LEDs and describes a set of 48 corresponding probe pairs 112. However the LED testing system 100 can include any number of probe pairs 112 for connection to any number of LEDs. The LED testing system 100 then sequentially energizes each LED from 1 to 48. The system LED testing system 100 synchronously measures light output using a photodetector 116 that views the entire probe area corresponding to LEDs 1 to 48. The system records the measured luminance, compares the measured luminance to limits, and records a result for each individual LED. The probe device 108 is then stepped to a next wafer sector 114 on wafer 102.

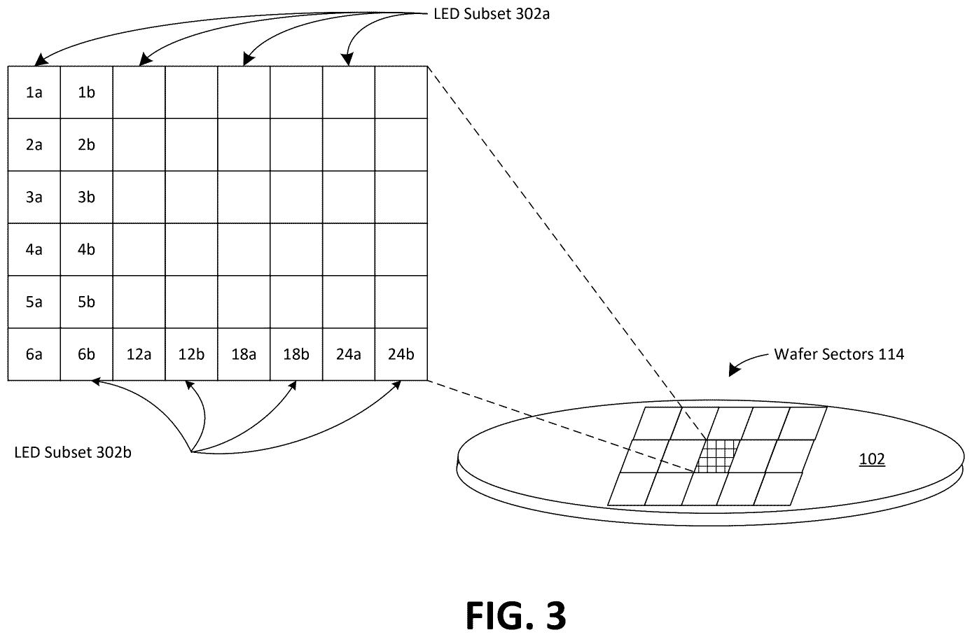

FIG. 3 illustrates an example of multiple LED subsets 302 in a single wafer sector 114 of a wafer 102 probed by the LED testing system 100 of FIG. 1, according to various embodiments. The wafer 102 includes, without limitation, one or more wafer sectors 114. The wafer sector 114 includes, without limitation, two or more LED subsets 302a and 302b (LED subsets 302). LED subset 302a includes, without limitation, LEDs numbered 1a through 24a. LED subset 302b includes, without limitation, LEDs numbered 1b through 24b.

In this example, a single wafer sector 114 includes multiple LED subsets 302. In some embodiments, a density of LEDs in the wafer sector 114 is greater than a density of probe pairs 112 of the probe device 108. As a result, the LEDs in the wafer sector 114 are separated into multiple testable LED subsets 302. The LED subset 302a is a probed LED subset if the LED subset 302a is connected to a corresponding set of LED probe pairs 112. The LED subset 302b is a probed LED subset if the LED subset 302b is connected to a corresponding set of LED probe pairs 112.

In operation, LED testing system 100 of FIG. 1 connects a probe pair 112 to each LED 1a to 24a, such that 24 probe pairs 112 are connected to the 24 LEDs of the LED subset 302a concurrently. The LED testing system 100 then sequentially energizes each LED from 1a to 24a. The system LED testing system 100 synchronously measures light output using a photodetector 116 that views the entire probe area corresponding to LEDs 1a to 24a and/or the wafer sector 114. The system records the measured luminance, compares the measured luminance to limits, and records a result for each individual LED. The probe device 108 is then stepped to the next LED subset 302b in the same wafer sector 114.

The LED testing system 100 connects a probe pair 112 to each LED 1a to 24a, such that 24 probe pairs 112 are connected to the 24 LEDs of the LED subset 302b concurrently. The LED testing system 100 then sequentially energizes each LED from 1b to 24b. The system LED testing system 100 synchronously measures light output using a photodetector 116 that views the entire probe area corresponding to LEDs 1b to 24b and/or the wafer sector 114. The probe device 108 is then stepped to the next wafer sector 114.

FIG. 4 illustrates an example of a probed LED subset 202 and a current and luminance graph 400 for individual LED testing using the LED testing system 100 of FIG. 1, according to various embodiments. The probed LED subset 202 includes, without limitation, one or more LEDs shown numbered 1 to 48. The graph 400 includes, without limitation, one or more energizing pulses 402, a lower luminance threshold 404, an upper luminance threshold 406, one or more LED identification boundary times 408, one or more LED identification time windows 410, and a luminance curve 412.

The upper portion of graph 400 shows energizing pulses 402-1, 402-2, 402-10, and 402-48, corresponding to LEDs 1, 2, 10, and 48, respectively. The LED testing system 100 also applies other energizing pulses 402. For example, energizing pulse 402-1 energizes LED 1, energizing pulse 402-2 energizes LED 2, energizing pulse 402-3 (not shown) energizes LED 3, energizing pulse 402-4 (not shown) energizes LED 4, and so on. Each energizing pulse 402 corresponds to a current curve, a voltage curve, a power curve, or another measure of a programmable VI source that biases the corresponding LED to a specific value at a precise moment in time, according to an energizing pattern or sequence.

The lower portion of graph 400 also shows luminance curve 412 detected by photodetector 116 and/or analyzed using the computing device 106. The lower portion of graph 400 also shows an individual luminance for each of the LEDs 1 to 48, shown as dashed lines. The luminance curve 412 is a result of overlapping light outputs of the LEDs 1 to 48 resulting from overlapping energizing pulses 402.

The lower luminance threshold 404 and the upper luminance threshold 406 are thresholds stored by the computing device 106. In some embodiments, at least a subset of the LED identification boundary times 408 are times where contiguous (e.g., sequentially adjacent, even if partially overlapping) energizing pulses 402 are equivalent to one another. In some embodiments, an LED identification boundary time 408 for a first LED (e.g., LED 1) is at a start time “0” of the energizing pattern, and an LED identification boundary time 408 for a last LED (e.g., LED 48) is at an end time of the energizing pattern. In some embodiments, an LED identification boundary time 408 for a first LED (e.g., LED 1) is a time where the energizing pulse for the first LED crosses a lower threshold energizing value (e.g., a lower threshold current), and an LED identification boundary time 408 for a last LED (e.g., LED 48) is a time where the energizing pulse for the last LED crosses the lower threshold energizing value. The LED identification boundary time 408 that is indicated in graph 400 corresponds to the LED identification boundary time 408 between contiguous energizing pulses 402-1 and 402-2. For clarity purposes, the other LED identification boundary times 408 are not labeled. In some embodiments, the LED identification boundary times 408 are times where LED output of contiguous LEDs in the energizing pattern are equivalent to one another.

An LED identification time window 410 is a time window or duration of time between two LED identification boundary times 408. The specifically called out LED identification time window 410 is an LED identification time window 410 for the LED 10. For clarity purposes, the other LED identification time windows 410 are not labeled.

The computing device 106 causes the LED testing system 100 to initiate a test that applies the energizing pulses 402 over time according to an energizing pattern. The computing device 106 determines that the luminance curve 412 exceeds the lower luminance threshold 404 and then monitors the luminance curve 412 to determine whether the luminance curve 412 remains within an acceptable range of values between the lower luminance threshold 404 and the upper luminance threshold 406.

In the example shown, the luminance curve 412 remains within an acceptable range of values until the LED identification time window 410 for the LED 10. The computing device 106 compares the value of the luminance curve 412 or a corresponding luminance measurement signal to the lower luminance threshold 404 and the upper luminance threshold 406. In this example, the computing device 106 determines that a value or magnitude of the luminance curve 412 is less than the lower luminance threshold 404. The computing device 106 identifies a timestamp of the luminance curve 412 or a corresponding luminance measurement signal and determines a time when the luminance curve 412 is less than the lower luminance threshold 404. The computing device 106 compares the time to LED identification time windows 410 and/or LED identification boundary times 408 specified in data describing the energizing pattern.

The data describing the energizing pattern specifies the one or more LED identification boundary times 408 and/or the one or more LED identification time windows 410. The computing device 106 determines that the time when the luminance curve 412 is less than the lower luminance threshold 404 corresponds to a particular LED identification time window 410. The data describing the energizing pattern includes a mapping that maps LED identification time windows 410 to corresponding LEDs and/or probe pairs 112. In some embodiments, the mapping maps an LED identification time window 410 to a probe pair 112 and maps the probe pair 112 to an LED. The mapping of a probe pair 112 to an LED is updated when the probe device 108 is moved to another set of LEDs.

The computing device 106 identifies an LED that is mapped to the LED identification time window 410 when the luminance curve 412 is less than the lower luminance threshold 404. The computing device 106 determines that the LED 10 failed the test and records a failing or unacceptable quality control result for LED 10. The computing device 106 determines that LEDs 1 to 9 and 11 to 48 have passed the test and records a failing or unacceptable quality control result for LEDs 1 to 9 and 11 to 48.

FIG. 5 illustrates an example of a probed LED subset 202 and a current and luminance graph 500 for LED group testing using the LED testing system 100 of FIG. 1, according to various embodiments. The probed LED subset 202 includes, without limitation, one or more LEDs shown numbered 1 to 48. The graph 500 includes, without limitation, one or more group energizing pulses 502, a group lower luminance threshold 504, a group upper luminance threshold 506, one or more LED group identification boundary times 508, one or more LED group identification time windows 510, and a group luminance curve 512.

In the embodiment shown, the individual LEDs are numbered as seen in FIG. 4. LED groups are shown in bold numbering and outlined using a bold line. For example, LED group 1 includes LEDs 1, 2, 7, and 8; LED group 2 includes LEDs 3, 4, 9, and 10; LED group 3 includes LEDs 5, 6, 11, and 12; LED group 4 includes LEDs 13, 14, 19, and 20; and so on.

The upper portion of graph 500 shows group energizing pulses 502-1, 502-2, 502-10, and 502-12, corresponding to LED groups 1, 2, 10, and 12, respectively. The LED testing system 100 also applies other group energizing pulses 502. For example, group energizing pulse 502-1 energizes LED group 1, group energizing pulse 502-2 energizes LED group 2, group energizing pulse 502-3 (not shown) energizes LED group 3, group energizing pulse 502-4 (not shown) energizes LED group 4, and so on. Each group energizing pulse 502 corresponds to a current curve, a voltage curve, a power curve, or another measure of a programmable VI source that biases the corresponding LEDs (and/or LED groups) to a specific value at a precise moment in time, according to a group energizing pattern or sequence.

In some embodiments, the LEDs in an LED group are connected, for example, using the probe pairs 112, circuitry of the probe device 108, and/or other circuitry so that a single group energizing pulse 502 energizes the LEDs in the LED group. However, in other examples, the energizing pattern includes a set of simultaneously applied (e.g., fully overlapping) energizing pulses for each LED group, so that four separate but simultaneously-applied energizing pulses are activated for LED group 1, four separate but simultaneously-applied energizing pulses are activated for LED group 2, and so on. Individual LEDs are connected to individual probe pairs 112.

The lower portion of graph 500 also shows group luminance curve 512 detected by photodetector 116 and/or analyzed using the computing device 106. In some examples, the value or magnitude of the group luminance curve 512 is greater than the luminance curve 412 (FIG. 4) for individual LEDs, because multiple LEDs are energized simultaneously. The lower portion of graph 500 also shows an individual luminance for each of the LED groups 1 to 12, shown as dashed lines. The luminance curve 512 is a result of overlapping light outputs of the LED groups 1 to 12 resulting from overlapping group energizing pulses 502.

The group lower luminance threshold 504 and the group upper luminance threshold 506 are thresholds stored by the computing device 106. In some examples, the value of the group lower luminance threshold 504 is greater than the lower luminance threshold 404 (FIG. 4) for individual LEDs, because multiple LEDs are energized simultaneously. In some examples, the value of the group upper luminance threshold 506 is greater than the upper luminance threshold 406 (FIG. 4) for individual LEDs, because multiple LEDs are energized simultaneously.

In some embodiments, at least a subset of the LED group identification boundary times 508 are times where contiguous (e.g., sequentially adjacent, even if partially overlapping) group energizing pulses 502 are equivalent to one another. Other LED group identification boundary times 508 can include a start time “0” and an end time of the energizing pattern of pulses. In some embodiments, an LED identification boundary time 508 for a first LED group (e.g., LED group 1) is a time where the energizing pulse for the first LED group crosses a lower threshold energizing value, and an LED identification boundary time 508 for a last LED group (e.g., LED group 12) is a time where the energizing pulse for the last LED group crosses the lower threshold energizing value. The LED identification boundary time 508 that is indicated in graph 500 corresponds to the LED identification boundary time 508 between contiguous group energizing pulses 502-1 and 502-2. For clarity purposes, the other LED group identification boundary times 508 are not labeled. In some embodiments, the LED group identification boundary times 508 are times where LED group luminance output of contiguous LED groups in the energizing pattern are equivalent to one another.

An LED group identification time window 510 is a time window or duration of time between two LED group identification boundary times 508. The specifically called out LED group identification time window 510 is an LED group identification time window 510 for the LED group 10, corresponding to LEDs 37, 38, 43, and 44. For clarity purposes, the other LED group identification time windows 510 are not labeled.

The computing device 106 causes the LED testing system 100 to initiate a test that applies the group energizing pulses 502 over time according to an energizing pattern. The computing device 106 determines that the group luminance curve 512 exceeds the group lower luminance threshold 504 and then monitors the group luminance curve 512 to determine whether the group luminance curve 512 remains within an acceptable range of values between the group lower luminance threshold 504 and the group upper luminance threshold 506.

In the example shown, the group luminance curve 512 remains within an acceptable range of values until the LED group identification time window 510 for the LED group 10. The computing device 106 compares the value of the luminance curve 512 or a corresponding luminance measurement signal to the group lower luminance threshold 504 and the group upper luminance threshold 506. In this example, the computing device 106 determines that a value or magnitude of the group luminance curve 512 is less than the group lower luminance threshold 504. The computing device 106 identifies a timestamp of the group luminance curve 512 or a corresponding luminance measurement signal and determines a time when the group luminance curve 512 is less than the group lower luminance threshold 504. The computing device 106 compares the time to LED group identification time windows 510 and/or LED group identification boundary times 508 specified in data describing the energizing pattern.

The data describing the energizing pattern specifies the one or more LED group identification boundary times 508 and/or the one or more LED group identification time windows 510. The computing device 106 determines that the time when the group luminance curve 512 is less than the lower luminance threshold 404 corresponds to a particular LED group identification time window 510. The data describing the energizing pattern includes a mapping that maps LED group identification time windows 510 to corresponding LED groups and/or corresponding sets of LEDs. In some embodiments, the mapping maps an LED group identification time window 510 to a set of probe pairs 112 and maps each probe pair 112 to an LED.

The computing device 106 identifies that LED group 10 is mapped to the LED group identification time window 510 when the group luminance curve 512 is less than the group lower luminance threshold 504. The computing device 106 determines that the LED group 10 failed the test and records a failing or unacceptable quality control result for LED group 10. The computing device 106 determines that LED groups 1 to 9, 11 and 12 have passed the test and records a passing or acceptable quality control result for LED groups 1 to 9, 11 and 12 (and/or for corresponding individual LEDs).

The group test is faster than the individual test because the duration of each LED group energizing pulse 502 can be as short in time as the energizing pulse 402 for a single LED. However, because the group test performed by the LED testing system 100 uses a single photodetector 116, the group test described above does not identify which individual LEDs of LED group 10 have failed. As a result, the computing device 106 performs an individual LED test that sequentially applies energizing pulses 402 to individual LEDs in sequence, as described with respect to FIG. 4, but limits the LEDs of the individual test to those of the failed one or more LED groups identified in the group test. In the example shown, only LED group 10 has failed, so the computing device 106 performs the individual test limited to LEDs 37, 38, 43, and 48. The computing device 106 determines which one or more of the LEDs 37, 38, 43, and 48 pass the individual test, and which one or more of the LEDs 37, 38, 43, and 48 fail the individual test. The computing device 106 records an individual quality control result for each of the LEDs 37, 38, 43, and 48.

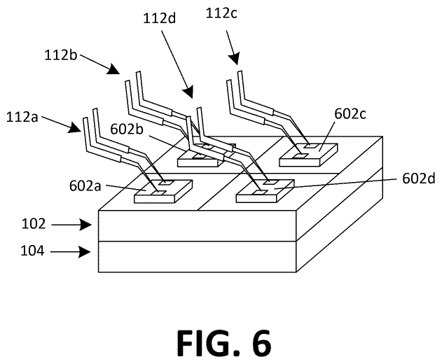

FIG. 6 illustrates an example of LED probe pairs 112 of LED testing system 100 of FIG. 1, according to various embodiments. The portion of the LED testing system 100 shown includes, without limitation, wafer chuck 104, wafer 102, one or more LED probe pairs 112a, 112b, 112c, and 112d (LED probe pairs 112), and one or more LEDs 602a, 602b, 602c, 602d (LEDs 602).

Each LED probe pair 112 connects the probe device 108 (FIG. 1) to an LED 602. For example, LED probe pair 112a connects the probe device 108 to LED 602a, LED probe pair 112b connects the probe device 108 to LED 602b, LED probe pair 112c connects the probe device 108 to LED 602c, LED probe pair 112d connects the probe device 108 to LED 602d. The probe device 108 includes any number of probe pairs 112. The probe device 108 is omitted from FIG. 6 for the purpose of clarity.

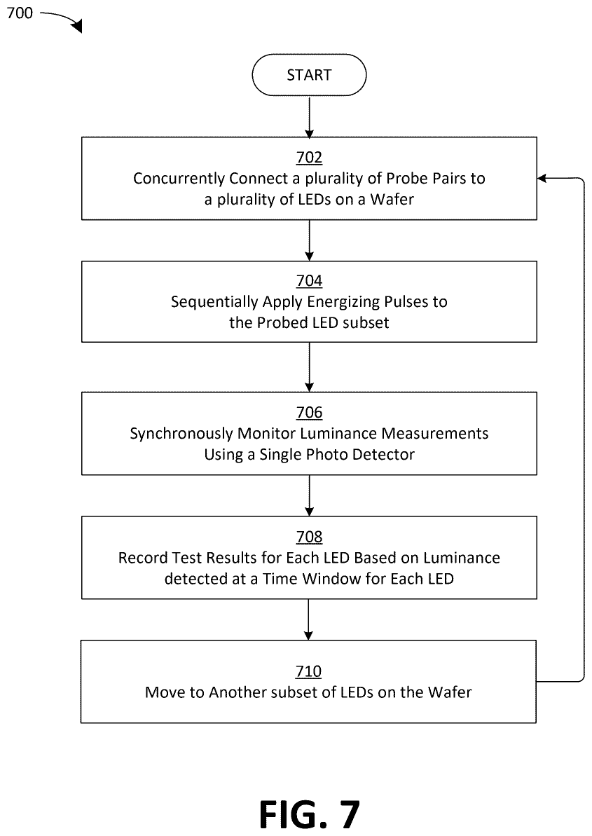

FIG. 7 is a flow diagram of method steps for individual LED testing using the LED testing system of FIG. 1, according to various embodiments. Although the method steps are described in conjunction with the systems and components of FIGS. 1-6, persons of ordinary skill in the art will understand that any system configured to perform the method steps, in any order, is within the scope of the invention.

As shown, a method 700 begins at step 702, where an LED testing system 100 concurrently connects probe pairs 112 to a corresponding set of LEDs 602 on a wafer 102. The LED testing system 100 includes a wafer chuck 104 that holds a wafer 102. The wafer 102 includes LEDs 602. The LED testing system 100 includes a probe device 108 that uses one or more probe pairs 112 that concurrently connect to a probed LED subset 202 corresponding to a subset of the LEDs 602 of the wafer 102. The LED testing system 100 includes a photodetector assembly 110 that is statically positioned as an energizing pattern is applied. The photodetector 116 and/or the light guide 118 of the photodetector assembly 110 is positioned to detect light emitted by all of the probed LED subset 202. Individual probe pairs 112 connect to individual LEDs 602 of the probed LED subset 202.

At step 704, the LED testing system 100 sequentially applies energizing pulses 402 to the LEDs 602 of the probed LED subset 202 on the wafer 102. The LED testing system 100 includes a computing device 106 that sequentially energizes the probed LED subset 202 by applying a plurality of energizing pulses 402. In some embodiments, the computing device 106 and/or the probe device 108 operate individually or in concert to sequentially apply the energizing pulses 402. Individual ones of the energizing pulses 402 energize individual LEDs 602 of the probed LED subset 202. In some embodiments, contiguous energizing pulses of the energizing pattern are activated with at least partial concurrence (e.g., overlapping in time). The computing device 106 causes the LED testing system 100 to perform a test of the probed LED subset 202. The test applies energizing pulses 402 over time according to an energizing pattern.

At step 706, the LED testing system 100 synchronously monitors luminance measurements using a photodetector 116. The photodetector 116 and/or the light guide 118 of the photodetector assembly 110 is positioned to detect light emitted by all of the LEDs 602 of the probed LED subset 202. The photodetector 116 detects light emitted from the LEDs 602 as a result of the energizing pulses applied to the LEDs 602. Because the photodetector 116 and/or the light guide 118 of the photodetector assembly 110 is positioned to detect light emitted by all of the LEDs 602, a single photodetector 116 is used for all luminance measurements. In some embodiments, the light guide 118 is a branched light guide, and the photodetector assembly 110 further includes a spectrometer 132 that measures spectral content (e.g., wavelength) of one or more of the LEDs 602. In some embodiments, spectral content detection is a spot check of a preconfigured or selected LED 602, as the wavelength of all LEDs 602 in a particular area of the wafer 102 are likely to have similar wavelength emissions.

The luminance measurements are synchronized with the sequential energizing pattern based on timing data for the energizing pattern. For example, the computing device 106 identifies and/or triggers luminance measurements at a time within an LED timing window for an LED 602. The computing device 106 monitors luminance by receiving one or more luminance measurement signals from the photodetector 116 and comparing the one or more luminance measurement signals to one or more luminance thresholds. The luminance thresholds include one or more of a lower luminance threshold 404 and/or an upper luminance threshold 406. The computing device 106 optionally monitors spectral content by receiving one or more spectral content measurement signals from the spectrometer 132 and comparing the one or more spectral content measurement signals to one or more spectral content or wavelength thresholds. The wavelength thresholds include one or more of a lower wavelength threshold and/or an upper wavelength threshold. In some embodiments, the LED testing system 100 measures and monitors spectral content for a subset of the LEDs 602 of the probed LED subset 202. In some embodiments, the subset corresponds to one spectral content measurement per “N” number of luminance measurements. In some embodiments, an enterprise specifies a set of LEDs 602 of the wafer 102 for spectral content measurement, for example, according to LED identifiers, and the LED testing system 100 limits measurement of spectral content to the specified LEDs 602.

At step 708, the LED testing system 100 records test results for each LED 602 of the probed LED subset 202. For example, the computing device 106 determines whether a portion of a luminance curve 412 corresponding to each LED 602 remains within an acceptable range of values between the lower luminance threshold 404 and the upper luminance threshold 406. Data stored in the computing device 106 logically associates each LED 602 with a portion of the luminance curve 412 corresponding to an LED identification time windows 410 and/or between two LED identification boundary times 408. For example, data describing the energizing pattern specifies the one or more LED identification boundary times 408 and/or the one or more LED identification time windows 410.

In some examples, the computing device 106 determines that a luminance curve 412 remains within an acceptable range of values throughout the test, and the computing device 106 records a passing or acceptable test result for each of the LEDs 602. However, if the computing device 106 determines that one or more portions of the luminance curve 412 is less than the lower luminance threshold 404 and/or greater than the upper luminance threshold 406, the computing device 106 records a failing or unacceptable test result for the one or more LEDs 602 corresponding the one or more portions of the luminance curve 412. The computing device 106 determines one or more times when the luminance curve 412 is outside the acceptable range of values, and uses data describing the energizing pattern to identify the one or more LEDs 602 based on the one or more times.

At step 710, the LED testing system 100 disconnects the probe pairs 112 from the presently probed LED subset 202, and moves to another (e.g., next) probed LED subset 202 of the wafer 102. In some embodiments, the LED testing system 100 moves the wafer chuck 104 away from the probe device 108 to disconnect the probe pairs 112. The LED testing system 100 laterally moves the wafer chuck 104 (e.g., in a plane of a surface of the wafer chuck 104 that is in contact with the wafer 102) so that the probe pairs 112 and the light guide 118 are aligned with the next probed LED subset 202 of the wafer 102. The LED testing system 100 moves the wafer chuck 104 towards the probe device 108 to connect the probe pairs 112 to the next probed LED subset 202. The process moves to step 702, where LED testing system 100 connects to the next probed LED subset 202 of the wafer 102.

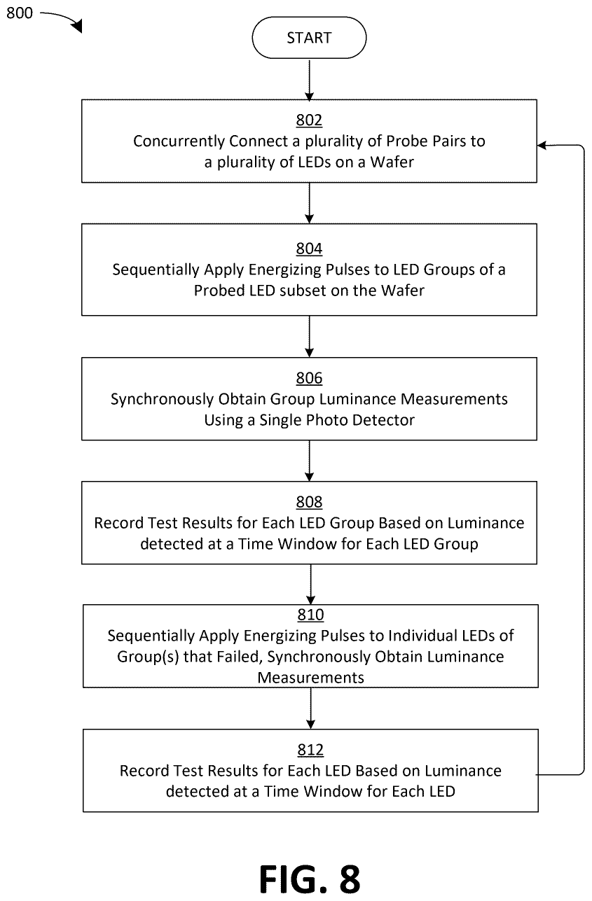

FIG. 8 is a flow diagram of method steps for LED group testing using the LED testing system of FIG. 1, according to various embodiments. Although the method steps are described in conjunction with the systems and components of FIGS. 1-6, persons of ordinary skill in the art will understand that any system configured to perform the method steps, in any order, is within the scope of the invention.

As shown, a method 800 begins at step 802, where an LED testing system 100 concurrently connects probe pairs 112 to a corresponding set of LEDs 602 on a wafer 102. The LED testing system 100 includes a wafer chuck 104 that holds a wafer 102. The wafer 102 includes LEDs 602. LED testing system 100 controls these LEDs 602 in LED groups. The LED testing system 100 includes a probe device 108 that uses one or more probe pairs 112 that concurrently connect to a probed LED subset 202 corresponding to a subset of the LEDs 602 of the wafer 102. An energizing pattern logically groups sets of LEDs 602 into LED groups. The LED testing system 100 includes a photodetector assembly 110 that is statically positioned as the energizing pattern is applied as a group-based test of the LEDs 602. Individual probe pairs 112 connect to individual LEDs 602 of the probed LED subset 202. In some embodiments, the energizing pattern includes a set of simultaneously-applied (e.g., fully overlapping) energizing pulses for each LED group, so that multiple separate but simultaneously-applied energizing pulses are activated for the LEDs 602 for an LED group. In some embodiments, the LEDs 602 in an LED group are connected, for example, using the probe pairs 112, circuitry of the probe device 108, and/or other circuitry so that a single group energizing pulse 502 energizes the LEDs 602 in the LED group. In either example, the photodetector 116 and/or the light guide 118 of the photodetector assembly 110 is positioned to detect light emitted by all of the probed LED subset 202.

At step 804, the LED testing system 100 sequentially applies group energizing pulses 502 to LED groups of the probed LED subset 202 on the wafer 102. The LED testing system 100 includes a computing device 106 that sequentially energizes the probed LED subset 202 by applying a plurality of group energizing pulses 502. In some embodiments, the computing device 106 and/or the probe device 108 operate individually or in concert to sequentially apply the group energizing pulses 502. The group energizing pulses 502 energize LED groups of the probed LED subset 202. In some embodiments, contiguous group energizing pulses 502 of the energizing pattern are activated with at least partial concurrence (e.g., overlapping in time). The computing device 106 causes the LED testing system 100 to perform a test of the probed LED subset 202. The test applies group energizing pulses 502 over time according to an energizing pattern.

At step 806, the LED testing system 100 monitors group luminance measurements using a photodetector 116. The photodetector 116 and/or the light guide 118 of the photodetector assembly 110 is positioned to detect light emitted by all of the LEDs 602 of all LED groups of the probed LED subset 202. The photodetector 116 detects light emitted from the LED groups as a result of the group energizing pulses 502 applied to the LED groups. Because the photodetector 116 and/or the light guide 118 of the photodetector assembly 110 is positioned to detect light emitted by all of the LED groups, a single photodetector 116 is used for all luminance measurements. In some embodiments, the light guide 118 is a branched light guide, and the photodetector assembly 110 further includes a spectrometer 132 that measures spectral content (e.g., wavelength) of one or more of the LED groups. In some embodiments, spectral content detection is a spot check of a preconfigured or selected LED group, as the wavelength of all LEDs 602 and LED groups in a particular area of the wafer 102 are likely to have similar wavelength emissions.

The luminance measurements are synchronized with the sequential energizing pattern based on timing data for the energizing pattern. For example, the computing device 106 identifies and/or triggers luminance measurements at a time within an LED timing window for an LED group. The computing device 106 monitors luminance by receiving one or more luminance measurement signals from the photodetector 116 and comparing the one or more group luminance measurement signals to one or more group luminance thresholds. The group luminance thresholds include one or more of a group lower luminance threshold 504 and/or a group upper luminance threshold 506. The computing device 106 optionally monitors spectral content by receiving one or more spectral content measurement signals from the spectrometer 132 and comparing the one or more spectral content measurement signals to one or more spectral content or wavelength thresholds. The wavelength thresholds include one or more of a lower wavelength threshold and/or an upper wavelength threshold. In some embodiments, the LED testing system 100 measures and monitors spectral content for a subset of the LEDs 602 and/or LED groups of the probed LED subset 202. In some embodiments, the subset corresponds to one spectral content measurement per “N” number of group luminance measurements. In some embodiments, an enterprise specifies a set of LEDs 602 and/or LED groups of the wafer 102 for spectral content measurement, for example, according to LED identifiers and/or LED group identifiers, and the LED testing system 100 limits measurement of spectral content to the specified LEDs 602 and/or LED groups (e.g., spectral content measurements are performed for LED groups corresponding to specified LEDs 602 and/or specified LED groups).

At step 808, the LED testing system 100 records test results for each LED group based on the LED group identification time windows 510 for each LED group. For example, the computing device 106 determines whether a portion of a group luminance curve 512 corresponding to each LED group remains within an acceptable range of values between the group lower luminance threshold 504 and the group upper luminance threshold 506. Data stored in the computing device 106 logically associates each LED group with a portion of the group luminance curve 512 corresponding to an LED group identification time window 510 and/or between two LED group identification boundary times 508. For example, data describing the energizing pattern specifies the one or more LED group identification boundary times 508 and/or the one or more LED group identification time window 510.

In some examples, the computing device 106 determines that a group luminance curve 512 remains within an acceptable range of values throughout the test, and the computing device 106 records a passing or acceptable test result for each of the LED groups. However, if the computing device 106 determines that one or more portions of the group luminance curve 512 is less than the group lower luminance threshold 504 and/or greater than the group upper luminance threshold 506, the computing device 106 records a failing or unacceptable test result for the one or more LED groups corresponding the one or more portions of the group luminance curve 512. The computing device 106 determines one or more times when the group luminance curve 512 is outside the acceptable range of values, and uses data describing the energizing pattern to identify the one or more LED groups based on the one or more times.

At step 810, the LED testing system 100 sequentially applies currents to individual LEDs of one or more LED group that have a failing or unacceptable test result, and synchronously obtains luminance measurements. The computing device 106 performs an individual LED test that sequentially applies energizing pulses 402 to individual LEDs in sequence, as described with respect to FIGS. 4 and 7. The computing device 106 limits this test to the LEDs 602 corresponding to the one or more LED groups identified to have a failing or unacceptable test result.

The LED testing system 100 sequentially applies energizing pulses 402 to the LEDs 602 corresponding to the one or more LED groups identified to have a failing test result. Individual ones of the energizing pulses 402 energize individual LEDs 602 of the probed LED subset 202. In some embodiments, contiguous energizing pulses of the energizing pattern are activated with at least partial concurrence. The LED testing system 100 also monitors luminance measurements of the individual test. The computing device 106 receives one or more luminance measurement signals from the photodetector 116 and comparing the one or more luminance measurement signals to one or more individual luminance thresholds. The luminance thresholds include one or more of a lower luminance threshold 404 and/or an upper luminance threshold 406. In some embodiments, the computing device 106 also monitors spectral content by receiving one or more spectral content measurement signals from the spectrometer 132 and comparing the one or more spectral content measurement signals to one or more spectral content or wavelength thresholds.

At step 812, the LED testing system 100 records test results for each LED 602 of the individual LED test. In some examples, the computing device 106 determines that a luminance curve 412 remains within an acceptable range of values throughout the test, and the computing device 106 records a passing or acceptable test result for each of the LEDs 602. However, if the computing device 106 determines that one or more portions of the luminance curve 412 is less than the lower luminance threshold 404 and/or greater than the upper luminance threshold 406, the computing device 106 records a failing or unacceptable test result for the one or more LEDs 602 corresponding the one or more portions of the luminance curve 412. The computing device 106 determines one or more times when the luminance curve 412 is outside the acceptable range of values, and uses data describing the energizing pattern to identify the one or more LEDs 602 based on the one or more times.

In some embodiments, once the group LED test and/or the individual LED are performed, the LED testing system 100 disconnects the probe pairs 112 from the presently probed LED subset 202, and moves to another (e.g., next) probed LED subset 202 of the wafer 102. In some embodiments, the LED testing system 100 moves the wafer chuck 104 away from the probe device 108 to disconnect the probe pairs 112. The LED testing system 100 laterally moves the wafer chuck 104 (e.g., in a plane of a surface of the wafer chuck 104 that is in contact with the wafer 102) so that the probe pairs 112 and the light guide 118 are aligned with the next probed LED subset 202 of the wafer 102. The LED testing system 100 moves the wafer chuck 104 towards the probe device 108 to connect the probe pairs 112 to the next probed LED subset 202. The process moves to step 802, where LED testing system 100 connects to the next probed LED subset 202 of the wafer 102.

In sum, the disclosed techniques involve sequentially energizing a probed LED subset on a wafer by applying a plurality of sequential energizing pulses that are synchronized with luminance and/or spectral measurement timing windows. Individual probe pairs connect to individual LEDs. Individual ones of the energizing pulses energize individual ones of the probed LEDs. In some embodiments, contiguous energizing pulses of the pattern are activated with at least partial concurrence (e.g., overlapping in time). Some embodiments include a chuck that holds the wafer that includes LEDs, a probe device that includes probe pairs that connect to a probed subset of the LEDs, and a photodetector assembly that is statically positioned to detect light emitted by all of the probed LED subset.

At least one technical advantage of the disclosed techniques relative to the prior art is that the disclosed techniques enable fast and reliable luminance testing prior to singulation. Another technical advantage is that the speed and efficiency of luminance testing is increased relative to existing techniques for luminance testing on wafer and/or prior to singulation. These technical advantages provide one or more technological advancements over prior art approaches.

.Aspects of the subject matter described herein are set out in the following numbered clauses.
1. In some embodiments, a computer-implemented method comprises connecting a plurality of probe pairs to a subset of a plurality of light emitting diodes (LEDs) of a wafer, sequentially applying a plurality of energizing pulses through the plurality of probe pairs, wherein the plurality of energizing pulses each energize individual ones of the subset of the plurality of LEDs, wherein contiguous ones of the plurality of energizing pulses are activated with at least partial concurrence, and synchronously detecting one or more luminance measurements for the subset of the plurality of LEDs using a photodetector assembly that is statically positioned to detect light emitted by all of the subset of the plurality of LEDs.
2. The method of clause 1, further comprising recording a test result for each LED of the subset of a plurality of LEDs based on the luminance measurements and one or more luminance thresholds.
3. The method of clauses 1 or 2, wherein the photodetector assembly comprises a light guide that captures and guides light emitted by all of the subset of the plurality of LEDs to a single photodetector.
4. The method of any of clauses 1-3, wherein the light guide comprises a bundle of optical fiber strands.
5. The method of any of clauses 1-4, wherein the photodetector assembly comprises a light guide that captures and guides light emitted by all of the subset of the plurality of LEDs to a photodetector and a spectrometer.
6. The method of any of clauses 1-5, wherein the contiguous ones of the plurality of energizing pulses are activated with at least partial concurrence by overlapping in time at least a portion of a first time window of a first energizing pulse with at least a portion of a second time window of a second energizing pulse.
7. The method of any of clauses 1-6, further comprising detecting spectral measurements for one or more of the subset of the plurality of LEDs using the spectrometer.
8. The method of any of clauses 1-7, further comprising disconnecting the plurality of probe pairs from the subset of the plurality of LEDs of the wafer, moving a wafer chuck based on LED location data for the plurality of probe pairs, and connecting the plurality of probe pairs to another subset of the plurality of LEDs.
9. The method of any of clauses 1-8, wherein the wafer is a transparent wafer, and the light emitted by all of the subset of the plurality of LEDs is emitted through a transparent wafer chuck that holds the wafer.
10. The method of any of clauses 1-9, wherein the plurality of LEDs are micro-LEDs that are less than 100 micrometers in size.
11. In some embodiments, a light emitting diode (LED) test system for testing LEDs on a wafer, the LED testing system comprises a chuck that holds a wafer comprising a plurality of LEDs, a probe device comprising a plurality of probe pairs that connect to a probed LED subset of the plurality of LEDs, wherein individual ones of the probe pairs connect to individual ones of the probed LED subset, a photodetector assembly that is statically positioned to detect light emitted by all of the probed LED subset, and at least one computing device that applies a plurality of energizing pulses, wherein individual ones of the plurality of energizing pulses each energize individual ones of the probed LED subset, and contiguous ones of the plurality of energizing pulses are activated with at least partial concurrence.
12. The LED test system of clause 11, wherein the at least one computing device further records a test result for each LED of the subset of a plurality of LEDs based on the luminance measurements and one or more luminance thresholds.
13. The LED test system of clauses 11 or 12, wherein the photodetector assembly comprises a light guide that captures and guides light emitted by all of the subset of the plurality of LEDs to a single photodetector.
14. The LED test system of any of clauses 11-13, wherein the light guide comprises a bundle of optical fiber strands.
15. The LED test system of any of clauses 11-14, wherein the photodetector assembly comprises a light guide that captures and guides light emitted by all of the subset of the plurality of LEDs to a photodetector and a spectrometer.
16. The LED test system of any of clauses 11-15, wherein the wafer is a transparent wafer, and the light emitted by all of the subset of the plurality of LEDs is emitted through a transparent wafer chuck that holds the wafer.
17. In some embodiments, one or more non-transitory computer-readable media store program instructions that, when executed by one or more processors, cause the one or more processors to perform a method comprising connecting a plurality of probe pairs to a subset of a plurality of light emitting diodes (LEDs) of a wafer, sequentially applying a plurality of group energizing pulses through the plurality of probe pairs, wherein the plurality of group energizing pulses each energize LED groups comprising two or more LEDs of the subset of the plurality of LEDs, wherein contiguous ones of the plurality of group energizing pulses are activated with at least partial concurrence, and detecting one or more luminance measurements using a photodetector assembly that is statically positioned to detect light emitted by all of the subset of the plurality of LEDs.
18. The one or more non-transitory computer-readable media of clause 17, wherein the method further comprises recording a test result for each of the LED groups based on the luminance measurements and one or more group luminance thresholds.
19. The one or more non-transitory computer-readable media of clauses 17 or 18, wherein the method further comprises disconnecting the plurality of probe pairs from the subset of the plurality of LEDs of the wafer, moving a wafer chuck based on LED location data for the plurality of probe pairs, and connecting the plurality of probe pairs to another subset of the plurality of LEDs.
20. The one or more non-transitory computer-readable media of any of clauses 17-19, wherein the method further comprises determining that the luminance measurements for one or more LED groups is outside of an acceptable range of values based on one or more luminance thresholds, and performing an individualize test of a set of LEDs corresponding to the one or more LED groups to identify individual LEDs that caused the luminance measurements for one or more LED groups is outside of an acceptable range of values.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments can be embodied as a system, method or computer program product. Accordingly, aspects of the present disclosure can take the form of an entirely hardware embodiment, an entirely software embodiment (including firmware, resident software, micro-code, etc.) or an embodiment combining software and hardware aspects that can all generally be referred to herein as a “module,” a “system,” or a “computer.” In addition, any hardware and/or software technique, process, function, component, engine, module, or system described in the present disclosure can be implemented as a circuit or set of circuits. Furthermore, aspects of the present disclosure can take the form of a computer program product embodied in one or more computer readable medium(s) having computer readable program code embodied thereon.

Any combination of one or more computer readable medium(s) can be utilized. The computer readable medium can be a computer readable signal medium or a computer readable storage medium. A computer readable storage medium can be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium can be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions can be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors can be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams can represent a module, segment, or portion of code, which comprises one or more executable instructions for implementing the specified logical function(s). It should also be noted that, in some alternative implementations, the functions noted in the block can occur out of the order noted in the figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure can be devised without departing from the basic scope thereof, and the scope thereof is determined by the claims that follow.

What is claimed is:

1. A computer-implemented method, the method comprising:
connecting a plurality of probe pairs to a subset of a plurality of light emitting diodes (LEDs) of a wafer;
sequentially applying a plurality of energizing pulses through the plurality of probe pairs, wherein the plurality of energizing pulses each energize individual ones of the subset of the plurality of LEDs, wherein contiguous ones of the plurality of energizing pulses are activated with at least partial concurrence; and
synchronously detecting one or more luminance measurements for the subset of the plurality of LEDs using a photodetector assembly that is statically positioned to detect light emitted by all of the subset of the plurality of LEDs.

2. The method of claim 1, further comprising:
recording a test result for each LED of the subset of a plurality of LEDs based on the luminance measurements and one or more luminance thresholds.

3. The method of claim 1, wherein the photodetector assembly comprises a light guide that captures and guides light emitted by all of the subset of the plurality of LEDs to a single photodetector.

4. The method of claim 3, wherein the light guide comprises a bundle of optical fiber strands.

5. The method of claim 1, wherein the photodetector assembly comprises a light guide that captures and guides light emitted by all of the subset of the plurality of LEDs to a photodetector and a spectrometer.

6. The method of claim 5, wherein the contiguous ones of the plurality of energizing pulses are activated with at least partial concurrence by overlapping in time at least a portion of a first time window of a first energizing pulse with at least a portion of a second time window of a second energizing pulse.

7. The method of claim 5, further comprising:
detecting spectral measurements for one or more of the subset of the plurality of LEDs using the spectrometer.

8. The method of claim 1, further comprising:
disconnecting the plurality of probe pairs from the subset of the plurality of LEDs of the wafer;
moving a wafer chuck based on LED location data for the plurality of probe pairs; and
connecting the plurality of probe pairs to another subset of the plurality of LEDs.

9. The method of claim 1, wherein the wafer is a transparent wafer, and the light emitted by all of the subset of the plurality of LEDs is emitted through a transparent wafer chuck that holds the wafer.

10. The method of claim 9, wherein the plurality of LEDs are micro-LEDs that are less than 100 micrometers in size.

11. A light emitting diode (LED) test system for testing LEDs on a wafer, the LED testing system comprising:
a chuck that holds a wafer comprising a plurality of LEDs;
a probe device comprising a plurality of probe pairs that connect to a probed LED subset of the plurality of LEDs, wherein individual ones of the probe pairs connect to individual ones of the probed LED subset;
a photodetector assembly that is statically positioned to detect light emitted by all of the probed LED subset; and
at least one computing device that applies a plurality of energizing pulses, wherein individual ones of the plurality of energizing pulses each energize individual ones of the probed LED subset, and contiguous ones of the plurality of energizing pulses are activated with at least partial concurrence.

12. The LED test system of claim 11, wherein the at least one computing device further records a test result for each LED of the subset of a plurality of LEDs based on the luminance measurements and one or more luminance thresholds.

13. The LED test system of claim 11, wherein the photodetector assembly comprises a light guide that captures and guides light emitted by all of the subset of the plurality of LEDs to a single photodetector.

14. The LED test system of claim 13, wherein the light guide comprises a bundle of optical fiber strands.

15. The LED test system of claim 11, wherein the photodetector assembly comprises a light guide that captures and guides light emitted by all of the subset of the plurality of LEDs to a photodetector and a spectrometer.

16. The LED test system of claim 11, wherein the wafer is a transparent wafer, and the light emitted by all of the subset of the plurality of LEDs is emitted through a transparent wafer chuck that holds the wafer.

17. One or more non-transitory computer-readable media storing program instructions that, when executed by one or more processors, cause the one or more processors to perform a method comprising:
connecting a plurality of probe pairs to a subset of a plurality of light emitting diodes (LEDs) of a wafer;
sequentially applying a plurality of group energizing pulses through the plurality of probe pairs, wherein the plurality of group energizing pulses each energize LED groups comprising two or more LEDs of the subset of the plurality of LEDs, wherein contiguous ones of the plurality of group energizing pulses are activated with at least partial concurrence; and
detecting one or more luminance measurements using a photodetector assembly that is statically positioned to detect light emitted by all of the subset of the plurality of LEDs.

18. The one or more non-transitory computer-readable media of claim 17, wherein the method further comprises:
recording a test result for each of the LED groups based on the luminance measurements and one or more group luminance thresholds.

19. The one or more non-transitory computer-readable media of claim 17, wherein the method further comprises:
disconnecting the plurality of probe pairs from the subset of the plurality of LEDs of the wafer;
moving a wafer chuck based on LED location data for the plurality of probe pairs; and
connecting the plurality of probe pairs to another subset of the plurality of LEDs.

20. The one or more non-transitory computer-readable media of claim 17, wherein the method further comprises:
determining that the luminance measurements for one or more LED groups is outside of an acceptable range of values based on one or more luminance thresholds; and
performing an individualize test of a set of LEDs corresponding to the one or more LED groups to identify individual LEDs that caused the luminance measurements for one or more LED groups is outside of an acceptable range of values.
